(19) United States
(12) Patent Application Publication
(10) Pub. No.: US 2017/0135247 A1
(43) Pub. Date: May 11, 2017

(54) HEAT TRANSFER DEVICE AND ELECTRONIC DEVICE

(71) Applicant: FUJITSU LIMITED, Kawasaki-shi (JP)

(72) Inventor: Susumu Ogata, Isehara (JP)

(73) Assignee: FUJITSU LIMITED, Kawasaki-shi (JP)

(21) Appl. No.: 15/416,247

(22) Filed: Jan. 26, 2017

Related U.S. Application Data
(63) Continuation of application No. PCT/JP2015/069113, filed on Jul. 2, 2015.

(30) Foreign Application Priority Data
Sep. 4, 2014 (JP) 2014-180286

(51) Int. Cl. H05K 7/20; F28D 15/02

(52) U.S. Cl. CPC H05K 7/20336; F28D 15/025; H05K 7/20327

(57) ABSTRACT

A heat transfer device according to the disclosure includes: a heated portion; a cooled portion; a closed loop-shaped flow channel meandering from the heated portion to the cooled portion; a step that divides the flow channel at the heated portion into a first portion and a second portion, where the second portion has a smaller cross-sectional area than a cross-sectional area of the first portion; and a working fluid enclosed in the flow channel.

### CROSS-REFERENCE TO RELATED APPLICATION(S)

This application is a continuation of International Patent Application No. PCT/JP2015/69113 filed on Jul. 2, 2015, which claims priority to Japanese Patent Application No. 2014-180286 filed on Sep. 4, 2014, and designated the U.S., the entire contents of which are incorporated herein by reference.

### FIELD

The embodiments discussed herein are related to a heat transfer device and an electronic device.

### BACKGROUND

Along with recent developments in information processing technology, small electronic devices such as mobile devices and wearable terminals are widely spreading. These electronic devices include heat-generating components such as CPUs (central processing units). In order to achieve size reduction of such an electronic device, it is effective to thin a heat transfer device that cools the heat-generating component.

A pulsating heat pipe or an oscillating heat pipe is one of the heat transfer devices effective for the thinning. The pulsating heat pipe has a structure in which a flow channel of a working fluid meanders from a heated portion to a cooled portion many times.

According to this structure, the working fluid is evaporated at the heated portion, which in turn increases the pressure in the flow channel of the heated portion. In contrast, the working fluid is condensed at the cooled portion, which in turn decreases the pressure in the flow channel of the cooled portion. Thus, pressure difference in the flow channel is caused between the heated portion and the cooled portion. With this pressure difference, the working fluid moves back and forth by itself in the flow channel, which makes it possible to transport the heat generated in the heated portion to the cooled portion. Here, a flow of the working fluid which moves back and forth in the flow channel in this manner is sometimes referred to as a pulsating flow.

The pulsating heat pipe can work simply by making the flow channel meander from the heated portion to the cooled portion, and therefore has a simple structure advantageous in size reduction.

However, when the temperature of the heat-generating component is raised and the temperature of the heated portion becomes high, the working fluid at the heated portion evaporates so much that the pressure in the flow channel at the heated portion more increases than is necessary. When this phenomena occurs, the working fluid cannot return back to the heated portion from the cooled portion, and thus the working fluid dries up at the heated portion. Such a phenomenon is called a dry-out.

When the dry-out occurs, an amount of the working fluid evaporated at the heated portion is reduced. As a consequence, the pulsating flow of the working fluid is scarcely generated, and a heat transfer capability of the pulsating heat pipe is significantly deteriorated.

A possible method for preventing such a dry-out is to create a circulating flow of the working fluid, in addition to the pulsating flow of the working fluid, such that the working fluid flows in one direction. This method can prevent the dry-out since the circulating flow constantly supplies the working fluid to the flow channel at the heated portion.

Various structures for creating the circulating flow are proposed, but still have room for improvement.

For example, in one proposed method, the working fluid is made to flow in the flow channel only in one direction by providing a check valve in the flow channel. In this method, however, the check valve complicates the structure of the pulsating heat pipe, thereby making it difficult to provide the pulsating heat pipe of smaller size.

Meanwhile, in another proposed method, a plurality of nozzles is provided in the flow channel, in an attempt to create the circulating flow. However, resistance acting on the working fluid from the nozzles increases in this structure, and hence it is made difficult for the working fluid to circulate the flow channel.

Furthermore, in still another proposed method, flow channels of wide width and narrow width are alternately arranged, in an attempt to create the circulating flow by using the difference in capillary force between the flow channels. However, when the width of the flow channel is made narrower in this manner, it is made difficult for the working fluid in the flow channel to radiate heat, thereby making it difficult to cool the working fluid at the cooled portion.

Note that techniques related to this application are described in the following documents:

Japanese Laid-open Patent Publication No. 63-318493;

Japanese Laid-open Patent Publication No. 07-332881;

Japanese Laid-open Patent Publication No. 2010-156533;

Japanese Laid-open Patent Publication No. 01-127895;

Japanese Laid-open Patent Publication No. 06-88685;

Toshihiro Fukuda et al., “Heat transport characteristics of pulsating heat pipes with non-uniform cross section”, Proceedings of 45th National Heat Transfer Symposium, Vol. I, p. 347-348, The Heat Transfer Society of Japan;

Yasushi Kato et al., “Study on Looped Heat Pipe with Non-uniform Cross Section (2nd Report: Effect of Channel Size)”, Proceedings of 40th National Heat Transfer Symposium, Vol. I, p. 313-314; and

Jin Kitajima et al., “Study on Looped Heat Pipe with Non-uniform Cross Section”, Proceedings of 39th National Heat Transfer Symposium, Vol. I, p. 147-148.

### SUMMARY

According to one aspect discussed herein, there is provided a heat transfer device including: a heated portion; a cooled portion; a closed loop-shaped flow channel meandering from the heated portion to the cooled portion; a step that divides the flow channel at the heated portion into a first portion and a second portion, where the second portion has a smaller cross-sectional area than a cross-sectional area of the first portion; and a working fluid enclosed in the flow channel.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a schematic diagram of a pulsating heat pipe;

FIG. 2 is a schematic diagram illustrating a case where a dry-out occurs in the pulsating heat pipe;

FIG. 3 is a graph schematically illustrating a problem to be caused by the dry-out;

FIG. 4 is a plan view of a heat transfer device according to an embodiment of the invention;

FIG. 5 is an enlarged sectional plan view of a flow channel located at a heated portion of the heat transfer device according to the embodiment;

FIG. 6 is an enlarged sectional plan view of the flow channel located at a cooled portion of the heat transfer device according to the embodiment;

FIG. 7 is an enlarged sectional plan view of the flow channel located between the heated portion and the cooled portion of the heat transfer device according to the embodiment;

FIG. 8 is a cross-sectional view of the flow channel included in the heat transfer device according to the embodiment, which is taken along an extending direction of the flow channel;

FIGS. 9A and 9B are schematic cross-sectional views for explaining cross-sectional areas of the flow channel included in the heat transfer device according to the embodiment;

FIG. 10 is an enlarged cross-sectional view for explaining an operation of the heat transfer device according to the embodiment;

FIG. 11 is an enlarged sectional plan view of the flow channel in the vicinity of the heated portion of the heat transport device according to a first example of the embodiment;

FIG. 12 is a cross-sectional view of the flow channel included in the heat transfer device according to the first example of the embodiment, which is taken along the extending direction of the flow channel;

FIG. 13 is an enlarged sectional plan view of the flow channel in the vicinity of the cooled portion of the heat transfer device according to a second example of the embodiment;

FIG. 14 is a cross-sectional view of the flow channel included in the heat transfer device according to the second example of the embodiment, which is taken along the extending direction of the flow channel;

FIG. 15 is a first cross-sectional view of the flow channel included in the heat transfer device according to a third example of the embodiment, which is taken along the extending direction of the flow channel;

FIG. 16 is a second cross-sectional view of the flow channel included in the heat transfer device according to the third example of the embodiment, which is taken along the extending direction of the flow channel;

FIG. 17 is a third cross-sectional view of the flow channel included in the heat transfer device according to the third example of the embodiment, which is taken along the extending direction of the flow channel;

FIG. 18 is a fourth cross-sectional view of the flow channel included in the heat transfer device according to the third example of the embodiment, which is taken along the extending direction of the flow channel;

FIG. 19 is a graph obtained as a result of an investigation for confirming the effect of the embodiment;

FIGS. 20A to 20D are cross-sectional views of the heat transfer device according to the embodiment, which are in the course of the manufacturing process;

FIG. 21A is a front view of an electronic device according to a first example of the embodiment;

FIG. 21B is a rear view of the electronic device according to the first example of the embodiment;

FIG. 22 is an exploded perspective view of the electronic device according to the first example of the embodiment;

FIG. 23 is an exploded perspective view of an electronic device according to a second example of the embodiment;

FIG. 24 is a cross-sectional view taken along the I-I line in FIG. 23;

FIG. 25 is a first perspective view illustrating an attitude of an electronic device in a third example of the embodiment when the electronic device is in use;

FIG. 26 is a second perspective view illustrating an attitude of the electronic device in the third example of the embodiment when the electronic device is in use; and

FIG. 27 is a third perspective view illustrating an attitude of the electronic device in the third example of the embodiment when the electronic device is in use.

### DESCRIPTION OF EMBODIMENTS

Prior to the description of the present embodiment, a dry-out occurring in a pulsating heat pipe will be described in detail.

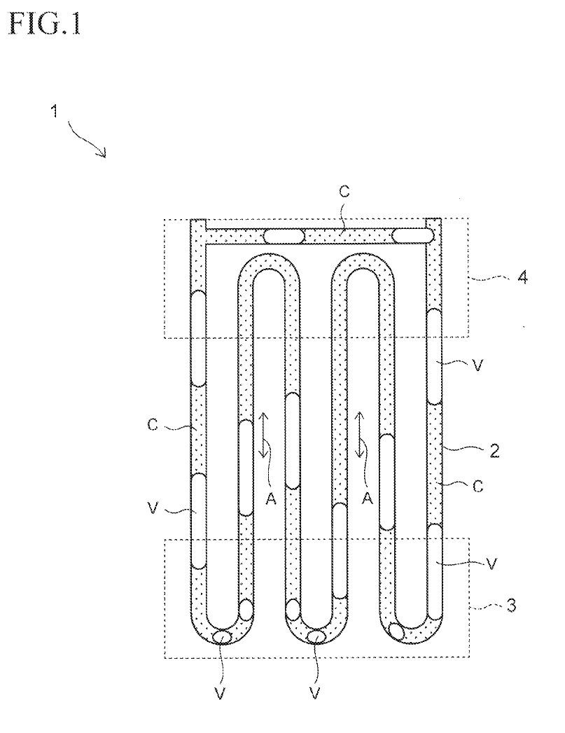

FIG. 1 is a schematic diagram of the pulsating heat pipe.

This pulsating heat pipe 1 is built in an electronic device such as a smartphone, and includes a heated portion 3, a cooled portion 4, and a closed loop-shaped flow channel 2 which meanders several times from and to these portions 3 and 4.

A working fluid C such as water or alcohol is enclosed in the flow channel 2. In this example, about a half of the volume of the flow channel 2 is filled with the working fluid C of the liquid phase. Moreover, bubbles V of the evaporated working fluid C are formed at portions in the flow channel 2 where the working fluid C is not present.

The heated portion 3 is a portion to which an unillustrated electronic component such as a CPU is thermally connected. At the heated portion 3, the heat from the electronic component evaporates the working fluid C and thus generates bubbles V. On the other hand, the cooled portion 4 is a portion to generate the working fluid C in the liquid phase by cooling down the bubbles V.

Generation of the bubbles V and condensation serves as a driving force of promoting the pulsation of the working fluid C in directions denoted by arrows A between the heated portion 3 and the cooled portion 4.

In this manner, a pulsating flow of the working fluid C can be obtained.

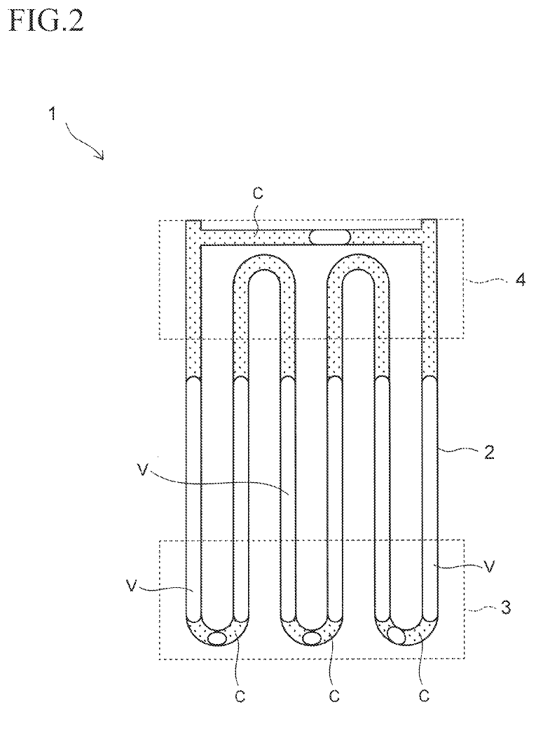

FIG. 2 is a schematic diagram illustrating the case where the dry-out occurs in the pulsating heat pipe 1.

As illustrated in FIG. 2, the dry-out is a phenomenon in which the bubbles V start to grow large at the heated portion 3, and hence the fluid C at the heated portion 3 is dried up. This phenomenon is likely to occur when a heat supplied to the heated portion 3 is increased due to a rise in temperature of the electronic component such as the CPU connected to the heated portion 3.

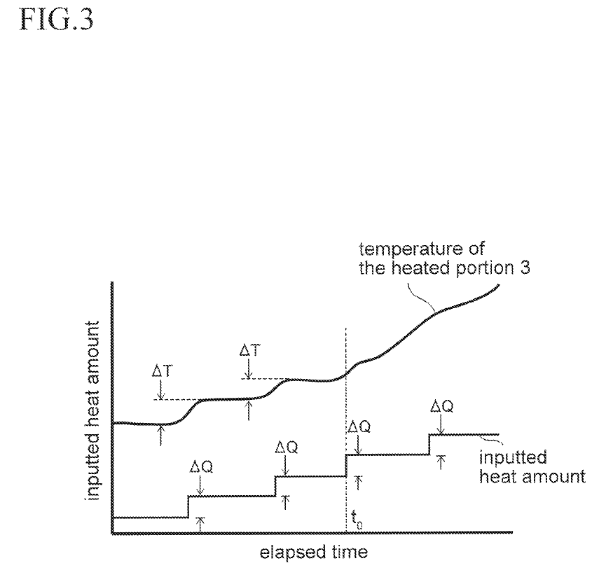

FIG. 3 is a graph schematically illustrating a problem caused by the dry-out.

The horizontal axis in FIG. 3 indicates the elapsed time, which is measured from the start of heating the heated portion 3. Meanwhile, the vertical axis in FIG. 3 indicates an inputted heat amount, which is inputted to the heated portion 3. Moreover, FIG. 3 also depicts a graph illustrating the temperature of the heated portion 3.

At the time points before time t₀ in FIG. 3, each time when the inputted heat amount is increased by an increment ΔQ, the temperature of the heated portion 3 rises by an increment ΔT accordingly.

However, after the time t₀, the temperature of the heated portion 3 rises, even when the inputted heat amount does not increase. This is thought to be happened because the working fluid C at the heated portion 3 is dried up due to the aforementioned dry-out, and thus the heat cannot be transported from the heated portion 3 to the cooled portion 4.

When such a dry out is occurred, the electronic component such as the CPU connected to the heated portion 3 cannot be appropriately cooled.

A possible solution to prevent the dry-out is to create a circulating flow in which the working fluid C flows in the closed loop-shaped flow channel 2 only in one direction, so as to constantly supply the working fluid C to the heated portion 3.

In the followings, an embodiment which enables the generation of a circulating flow with a simple structure will be described.

### Embodiment

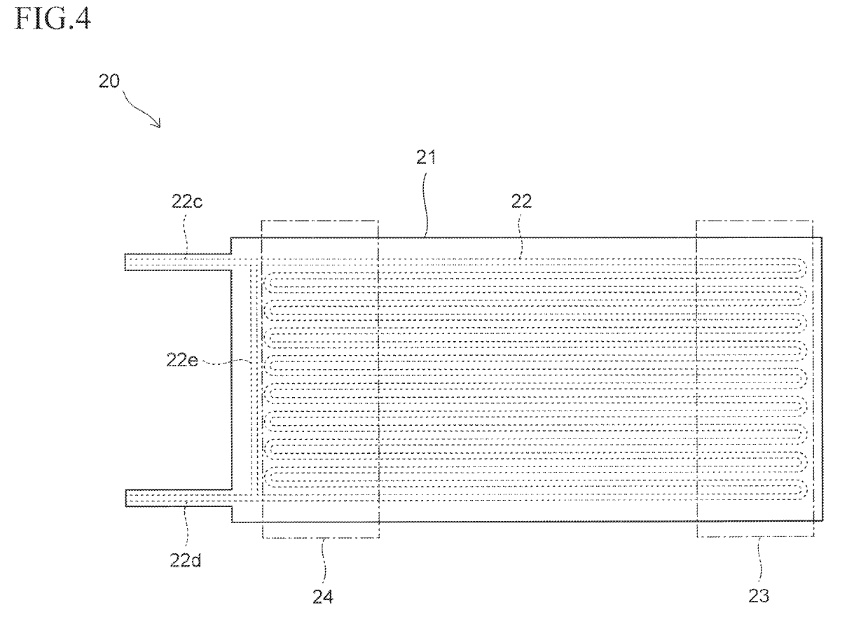

FIG. 4 is a plan view of a heat transfer device 20 according to a present embodiment.

The heat transfer device 20 is a pulsating heat pipe, which includes a sheet 21 such as a resin sheet, and a flow channel 22 formed in the sheet 21.

The flow channel 22 is formed to meander several times from and to a heated portion 23 and a cooled portion 24, which are provided at respective end portions of the sheet 21, and a working fluid such as water or ethanol is enclosed in the flow channel 22. In this example, about a half of the volume of the flow channel 22 is filled with the working fluid of the liquid phase. Note that a fluorine-based compound such as chlorofluorocarbon and hydrofluorocarbon may be used as the working fluid instead of water and ethanol.

Provided at the ends of the flow channel 22 is a first injection hole 22c and a second injection hole 22d, which are used to inject the working fluid into the flow channel 22 in the manufacturing process. Moreover, the injection holes 22c and 22d are connected to each other by a linear connection flow channel 22e. Thus, the flow channel 22 forms a closed loop.

Note that the injection holes 22c and 22d are sealed after the working fluid is injected into the flow channel 22.

The heated portion 23 is a portion to which an unillustrated electronic component such as a CPU is thermally connected, and the working fluid evaporates by the heat of the electronic component. On the other hand, the cooled portion 24 is a portion to cool and condense the evaporated working fluid.

Examples of a method of cooling the working fluid at the cooled portion 24 include an air cooling method and a water cooling method.

Although the planer size of the heat transfer device 20 is not particularly limited, the heat transfer device 20 is formed into a substantially rectangular shape having the long side of about 100 mm and the short side of about 50 mm in this example.

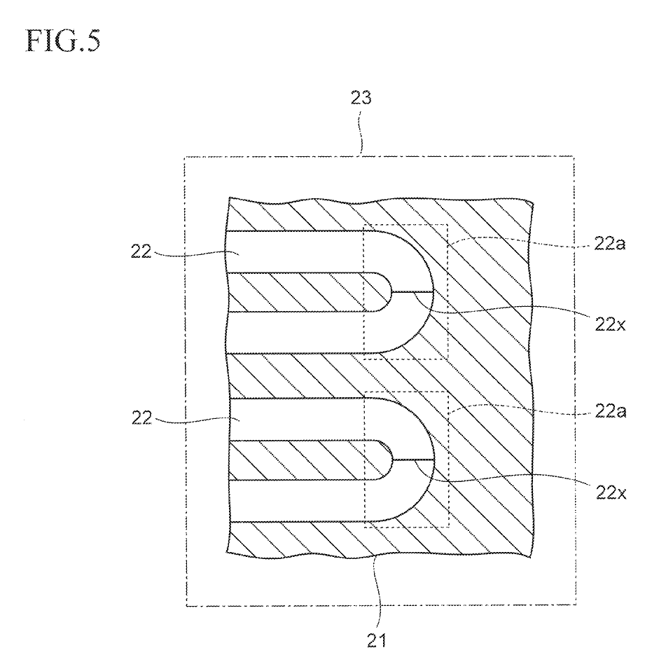

FIG. 5 is an enlarged sectional plan view of the flow channel 22 at the heated portion 23.

As illustrated in FIG. 5, the flow channel 22 includes first bent portions 22a bent into a U-shape at the heated portion 23, and a step 22x is provided on an inner wall of the flow channel 22 at the first bent portion 22a.

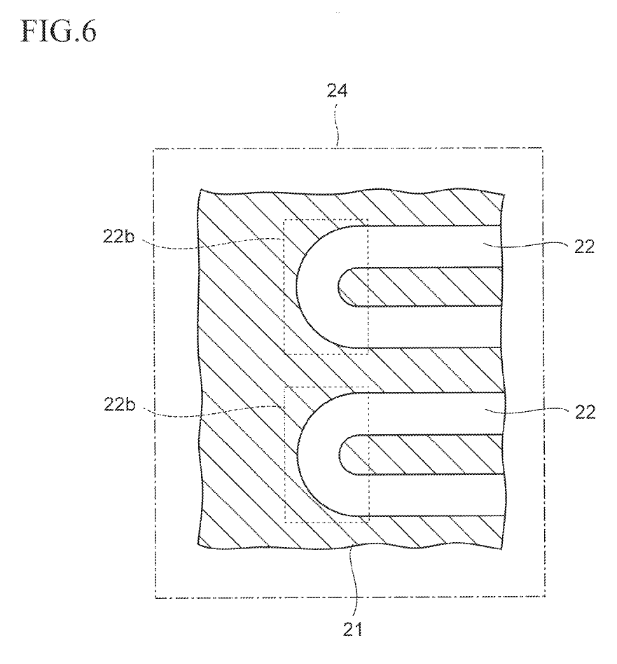

Meanwhile, FIG. 6 is an enlarged sectional plan view of the flow channel 22 at the cooled portion 24.

As illustrated in FIG. 6, the flow channel 22 includes second bent portions 22b bent into a U-shape at the cooled portion 24. However, unlike the first bent portion 22a, no step is provided at the second bent portion 22b.

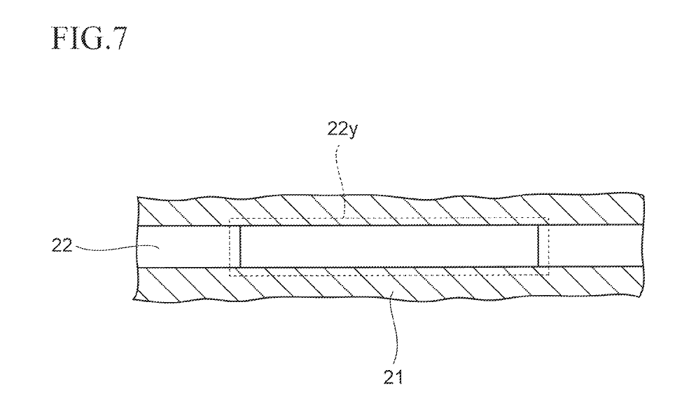

FIG. 7 is an enlarged sectional plan view of the flow channel 22 between the heated portion 23 and the cooled portion 24.

As illustrated in FIG. 7, the flow channel 22 extends straight between the heated portion 23 and the cooled portion 24, and an inclined portion 22y to be described later is provided on an inner wall of the flow channel 22.

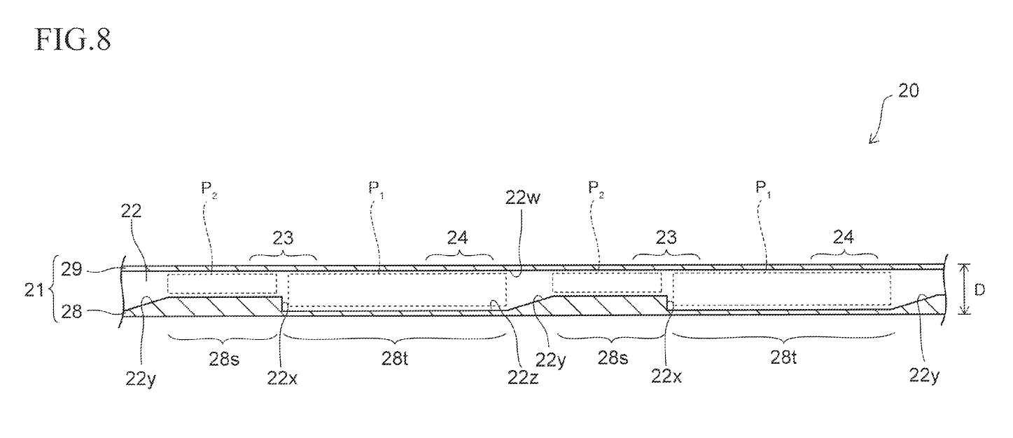

FIG. 8 is a cross-sectional view of the flow channel 22 taken along an extending direction thereof.

As illustrated in FIG. 8, the flow channel 22 repeatedly passes through the portion between the heated portion 23 and the cooled portion 24, and the aforementioned step 22x is provided at the flow channel 22 located in the heated portion 23.

Moreover, the sheet 21 includes a first sheet 28 and a second sheet 29. A top surface 22w and a bottom surface 22z of the flow channel 22 are defined by inner surfaces of the sheets 28 and 29.

Of these inner surfaces, the top surface 22w is flat. On the other hand, the bottom surface 22z is provided with the aforementioned step 22x. Thus, the cross-sectional area of the flow channel 22 changes along with the flow of the working fluid.

In the following, a portion of the flow channel 22, which is located on a lower side with respect to the step 22x and whose height is high, will be referred to as a first portion P₁. Then, a portion of the flow channel 22, which is located on an upper side with respect to the step 22x and whose height is low, will be referred to as a second portion P₂.

Note that the first portion P₁ corresponds to a portion delimited by the step 22x and having a larger cross-sectional area in the flow channel 22. Meanwhile, the second portion P₂ corresponds to a portion delimited by the step 22x and having a smaller cross-sectional area in the flow channel 22.

Moreover, the bottom surface 22z of the flow channel 22 is provided with the aforementioned inclined portions 22y in such a way as to be inclined upward from the first portion P₁ to the second portion P₂.

Meanwhile, the first sheet 28 is divided into a thick portion 28s and a thin portion 28t by the steps 22x and the inclined portion 22y.

Of these portions, the thick portion 28s is a portion of the first sheet 28 located below the second portion P₂ of the flow channel 22. Meanwhile, the thin portion 28t is a portion of the first sheet 28 located below the first portion P₁ of the flow channel 22, and which is thinner than the thick portion 28s.

Note that the entire thickness D of the heat transfer device 20 is not particularly limited. In this example, the thickness D is made equal to or below 0.5 mm, thereby thinning the electronic device that houses the heat transfer device 20.

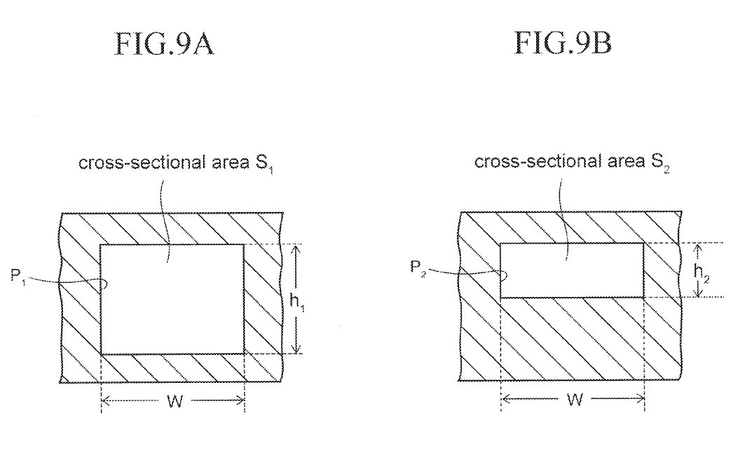

FIGS. 9A and 9B are schematic cross-sectional views for explaining the cross-sectional areas of the flow channel 22.

Of the drawings, FIG. 9A is a cross-sectional view of the first portion P₁ of the flow channel 22, and FIG. 9B is a cross-sectional view of the second portion P₂ of the flow channel 22. Note that the cutting plane in each of FIGS. 9A and 9B is a plane perpendicular to the extending direction of the flow channel 22.

In the following, the cross-sectional area of the first portion P₁ (FIG. 9A) located on the lower side with respect to the step 22x will be denoted by S₁, and the cross-sectional area of the second portion P₂ (FIG. 9B) located on the upper side with respect to the step 22x will be denoted by S₂.

A width W of the flow channel 22 is the same in the first portions P₁ and the second portions P₂. In this example, the width W is set to about 0.4 mm.

Meanwhile, as a consequence of providing the step 22x, a height h1 at the first portion P₁ becomes higher than a height h₂ at the second portion P₂. Hence, the cross-sectional area S₁ becomes larger than the cross-sectional area S₂.

Note that a preferred ratio between the cross-sectional areas S₁ and S₂ will be described later.

In the meantime, while the cross-sectional areas S₁ and S₂ are made different from each other by changing the heights h₁ and h₂ in this example, the way of making the cross-sectional areas different is not limited to this. For instance, the cross-sectional area S₁ may be made larger than the cross-sectional area S₂ by setting the width W of the flow channel 22 at the first portion P₁ wider than the width W of the flow channel 22 at the second portion P₂.

Next, an operation of the heat transfer device 20 of the present embodiment will be described.

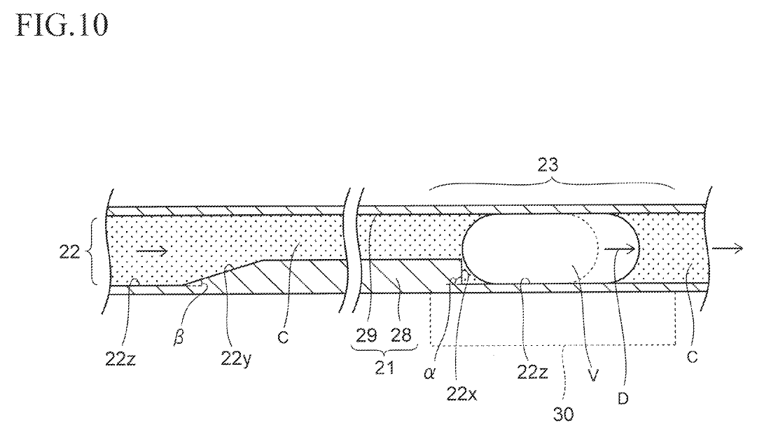

FIG. 10 is an enlarged cross-sectional view for explaining the operation of the heat transfer device 20. Note in FIG. 10 that the same elements as those explained in FIG. 8 will be denoted by the same reference numerals as in FIG. 8 and description thereof will be omitted below.

As illustrated in FIG. 10, an electronic component 30 such as a CPU is thermally connected to the first sheet 28 at the heated portion 23, and a working fluid C in the flow channel 22 is heated by the electronic component 30.

Thus, the working fluid C is evaporated and made into a bubble V at the heated portion 23. However, the bubble V gets caught on the above-mentioned step 22x. For this reason, the bubble V grows in the direction D away from the step 22x, and the working fluid C is pushed out by the bubble V.

The direction to push out the working fluid C is limited to the direction D away from the step 22x as mentioned above. In this way, the flowing direction of the working fluid C in the flow channel 22 is regulated and the circulating flow is thus obtained. As a consequence, it is possible to constantly supply the working fluid C to the flow channel 22 at the heated portion 23, and thus to prevent the aforementioned dry-out.

Here, when the step 22x is located away from the heated portion 23, the bubble V just generated at the heated portion 23 does not get caught on the step 22x but grows isotropically. As a consequence, the bubble V also moves in the direction opposite to the direction D. Accordingly, in order to fix the direction of growth of the bubble V and to reliably push the working fluid C out in the direction D, it is preferable to provide the step 22x in the flow channel 22 at the heated portion 23 as in the present embodiment.

Meanwhile, an angle α between a stepped surface of the step 22x and the bottom surface 22z is set to 90° in this example. However, the angle α is not limited to 90° and may be set slightly different than from 90°, so far as the direction of growth of the bubble V can be regulated to the direction D as described above.

Here, the cross-sectional area S₂ of the second portion P₂ only needs to be smaller than the cross-sectional area S₁ of the first portion P₁ so as to make the bubble V get caught in the flow channel 22. Accordingly, instead of making the width of the flow channel 22 constant as in this example, the cross-sectional area S₂ may be made smaller than the cross-sectional area S₁ by setting the width of the second portion P₂ narrower than the width of the first portion P₁, while interposing the step 22x between the first portion P₁ and second portion P₂.

Furthermore, since the inclined portions 22y are provided in the middle of the flow channel 22 in this example, the working fluid C smoothly flows in such a way as to crawl up the inclined portion 22y, and hence the resistance acting on the working fluid C from the flow channel 22 can be reduced.

An inclination angle β of the inclined portion 22y measured from the bottom surface 22z is not particularly limited. In this example, the inclination angle β is set in a range from about 1° to 5°.

Here, the step 22x plays the role of hooking the bubble V as described above. Accordingly, the position of the step 22x is not particularly limited so far as the step 22x is located at the heated portion 23 where the bubble V is generated.

Meanwhile, the inclined portion 22y plays the role of varying the cross-sectional area of the flow channel 22 while suppressing the resistance acting on the working fluid C from the flow channel 22. Accordingly, the position of the inclined portion 22y is not particularly limited, so far as the inclined portion 22y is located at the position other than the heated portion 23 where the bubble V is generated.

In the followings, examples of the positions of the step 22x, the inclined portion 22y, and the electronic component 30 will be described.

### First Example

In the first example, a preferred position of the step 22x will be described.

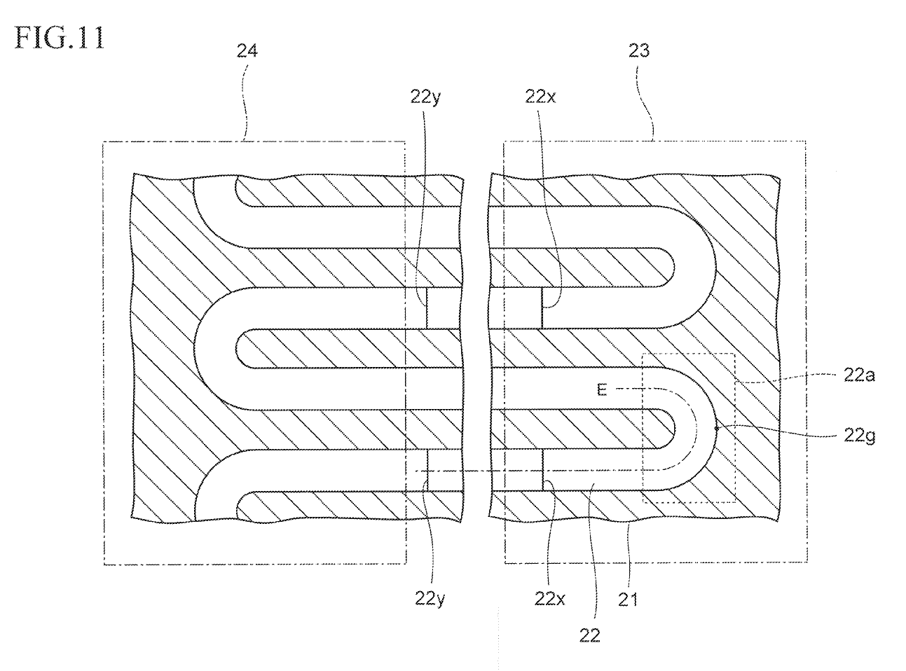

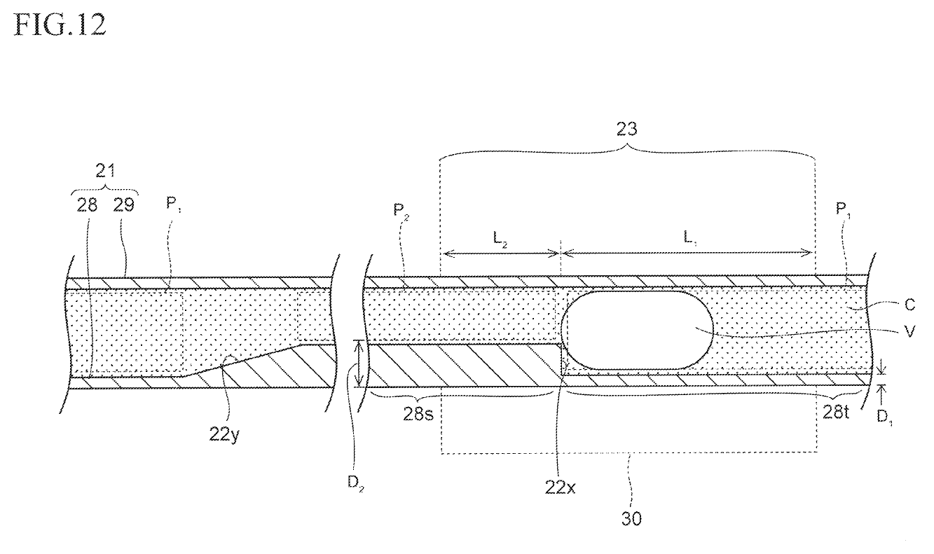

FIG. 11 is an enlarged sectional plan view of the flow channel 22 in the vicinity of the heated portion 23 of this example. FIG. 12 is a cross-sectional view of the flow channel 22 taken along an extending direction E thereof.

As illustrated in FIG. 11, in this example, the step 22x is brought closer to the cooled portion 24 by providing the step 22x at a position away from a peak 22g of the first bent portion 22a.

Thus, as illustrated in FIG. 12, of the flow channel 22 located at the heated portion 23, a length L₁ of the first portion P₁ becomes larger than a length L₂ of the second portion P₂, whereby a proportion of the first portion P₁ in the heated portion 23 becomes higher than that of the second portion P₂.

A thickness D₁ of the thin portion 28t below the first portion P₁ is thinner than a thickness D₂ of the thick portion 28s. Accordingly, the thin portion 28t can transfer the heat of the electronic component 30 to the working fluid C more efficiently than the thick portion 28s does.

For this reason, by setting the length L₁ equal to or above the length L₂ as in this example, the bubble V is more apt to be generated at the first portion P₁, so that the bubble V can easily generate the circulating flow as described previously.

### Second Example

In the second example, a preferred position of the inclined portion 22y will be described.

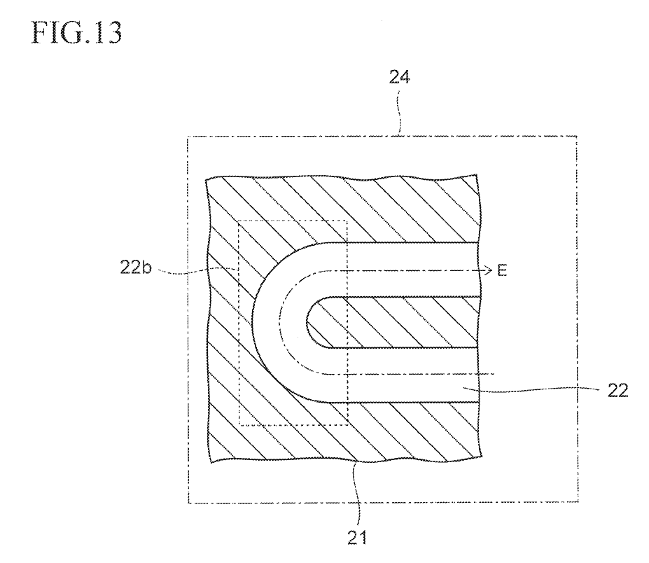

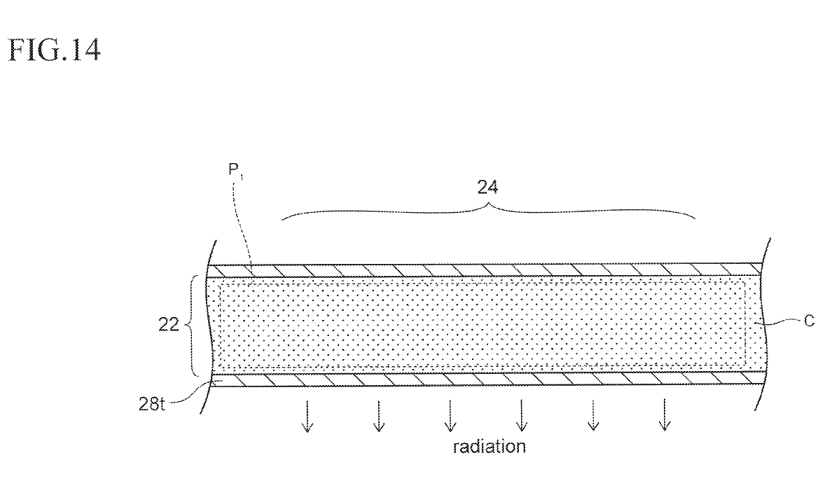

FIG. 13 is an enlarged sectional plan view of the flow channel 22 in the vicinity of the cooled portion 24 of this example. FIG. 14 is a cross-sectional view of the flow channel 22 taken along the extending direction E thereof.

As illustrated in FIGS. 13 and 14, in this example, the inclined portion 22y is located away from the cooled portion 24 such that the first portion P₁ occupies all of flow channel 22 at the cooled portion 24. According to this structure, only the thin portion 28t below the first portion P₁ is located at the cooled portion 24 as illustrated in FIG. 14. As a consequence, the heat of the working fluid C at the cooled portion 24 is promptly radiated to the outside through the thin portion 28t, whereby cooling efficiency of the working fluid C at the cooled portion 24 is increased.

### Third Example

In this example, exemplary positions of the electronic component 30 will be described.

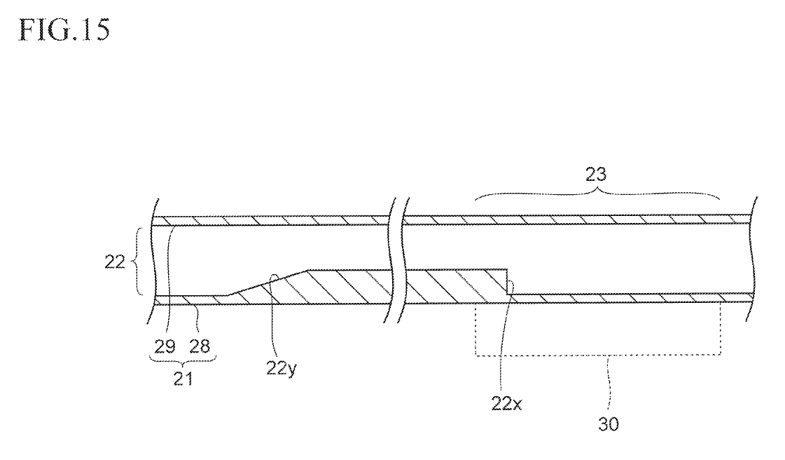

FIGS. 15 to 18 are cross-sectional views taken along the extending direction of the flow channel 22 of these examples.

In the example of FIG. 15, the electronic component 30 is thermally connected to the first sheet 28 at the heated portion 23.

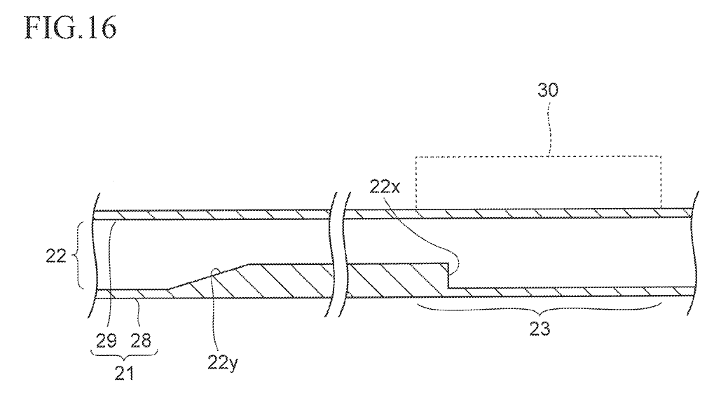

In the example of FIG. 16, the electronic component 30 is thermally connected to the second sheet 29 at the heated portion 23.

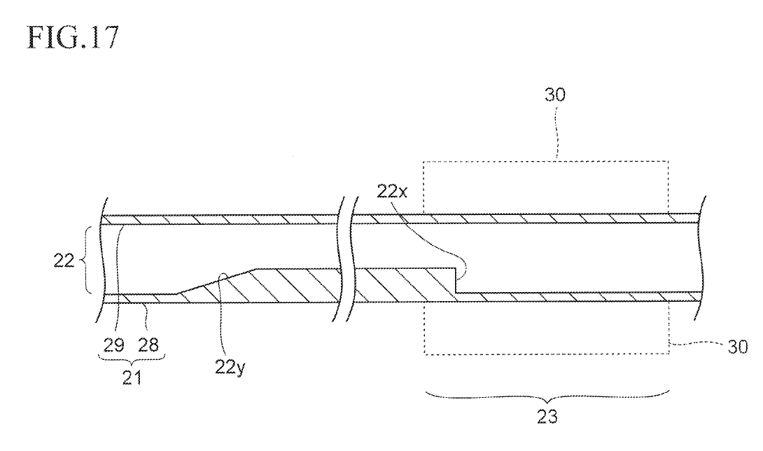

Moreover, in the example of FIG. 17, the two electronic components 30 are provided, and the electronic components 30 are thermally connected to the first sheet 28 and the second sheet 29 at the heated portion 23, respectively.

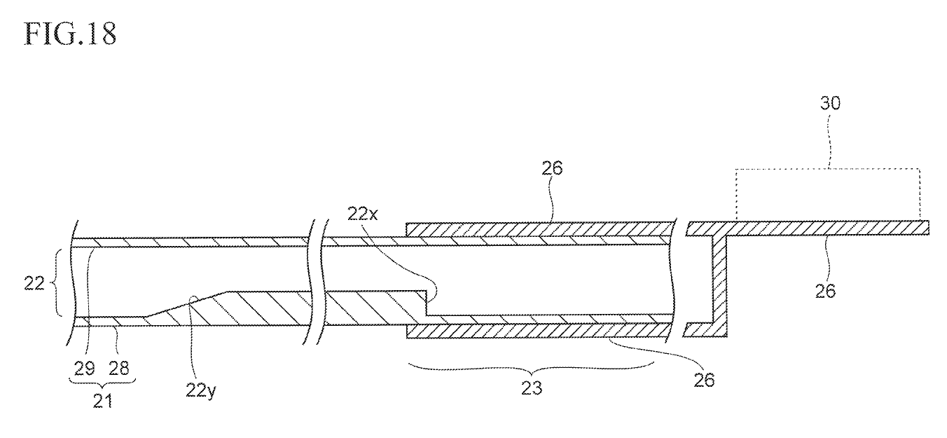

Meanwhile, in the example of FIG. 18, a heat transfer member 26 made of a metal is connected, respectively, to the first sheet 28 and the second sheet 29 at the heated portion 23. Then, the electronic component 30 is connected to the heat transfer member 26. Thus, the heat of the electronic component 30 is transferred to the flow channel 22 via the heat transfer member 26.

In any of the examples of FIGS. 15 to 18 described above, the heat of the electronic component 30 can evaporate the working fluid C at the heated portion 23.

### Experimental Example

Next, a description will be given of an investigation conducted by the inventor of the present application in order to confirm the effect of the present embodiment.

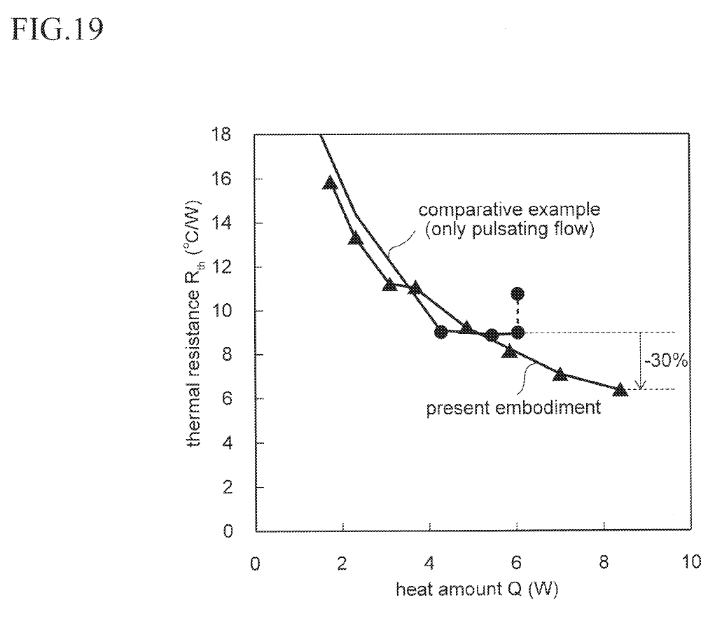

FIG. 19 is a graph obtained by the investigation.

In this investigation, a relation between a heat amount Q to be transported from the heating ported 23 to the cooled portion 24 by the working fluid in the flow channel 22 and thermal resistance Rₜₕ of the heat transfer device 20 was examined.

Here, a ratio S₂/S₁ of the cross-sectional area S₂ of the second portion P₂ of the flow channel 22 to the cross-sectional area S₁ of the first portion P₁ of the flow channel 22 illustrated in FIGS. 9A and 9B was set to 0.7.

In the meantime, a heat transfer device prepared by omitting the connection flow channel 22e (see FIG. 4) from the heat transfer device 20 of the present embodiment was used as a comparative example, and the heat transfer device of the comparative example was also subjected to the same investigation. In the comparative example, circulating flow of the working fluid does not generate, as a consequence of the omission of the connection flow channel 22e. Instead, the pulsating flow of the working fluid is generated in the comparative example.

As illustrated in FIG. 19, in the comparative example in which only the pulsating flow generates, the thermal resistance Rₜₕ was sharply increased when the heat amount Q becomes 6 W. This is because the dry-out occurs, and hence the heat transport capability of the heat transfer device is deteriorated.

On the other hand, in the present embodiment, the thermal resistance Rₜₕ was not increased even when the heat amount Q becomes 8 W. Thus, it was clarified that a dry-out did not occur in the heat transfer device of the present embodiment.

Furthermore, comparison between the lowest values of the thermal resistance Rₜₕ of the comparative example and the present embodiment shows that the lowest value of the present embodiment is about 30% less than that of the comparative example. Since the heat transfer rate is inversely proportional to the thermal resistance Rₜₕ, it follows that the heat transfer rate of the heat transfer device 20 of the present embodiment is about 1.4 times as large as that of the comparative example.

From these facts, it is effective for improving the heat transfer performance of the heat transfer device 20 to provide the step 22x in the flow channel 22 at the heated portion 23 as in the present embodiment.

Note that this investigation was conducted by setting the ratio S₂/S₁ of the cross-sectional areas of the flow channel 22 located upward and downward of the step 22x to 0.7 as described above. However, when the same investigation was conducted by setting the ratio S₂/S₁ to 0.5, neither the circulating nor pulsating flow of the working fluid occurred.

Therefore, it is preferable to set the minimum value of the ratio S₂/S₁ to 0.6 in order to cause the heat transfer device 20 to perform the heat transportation while generating the circulating flow and the pulsating flow.

As described above, according to the heat transfer device 20 of the present embodiment, the circulating flow of the working fluid C can be obtained by providing the step 22x to the flow channel 22 at the heated portion 23, which in turn prevents the dry-out from occurring at the heated portion 23.

As a consequence, it is made possible to reduce the thermal resistance of the heat transfer device and to improve the heat transfer performance thereof.

In addition, the circulating flow can be obtained without using a check valve. Thus, the structure of the heat transfer device 20 is made simple and the thinning of the heat transfer device 20 is facilitated.

In the meantime, no movable parts are needed to obtain the circulating flow. Thus, it is possible to provide the heat transfer device 20 which is less breakable.

### Manufacturing Method

Next, a manufacturing method of a heat transfer device according to the present embodiment will be described.

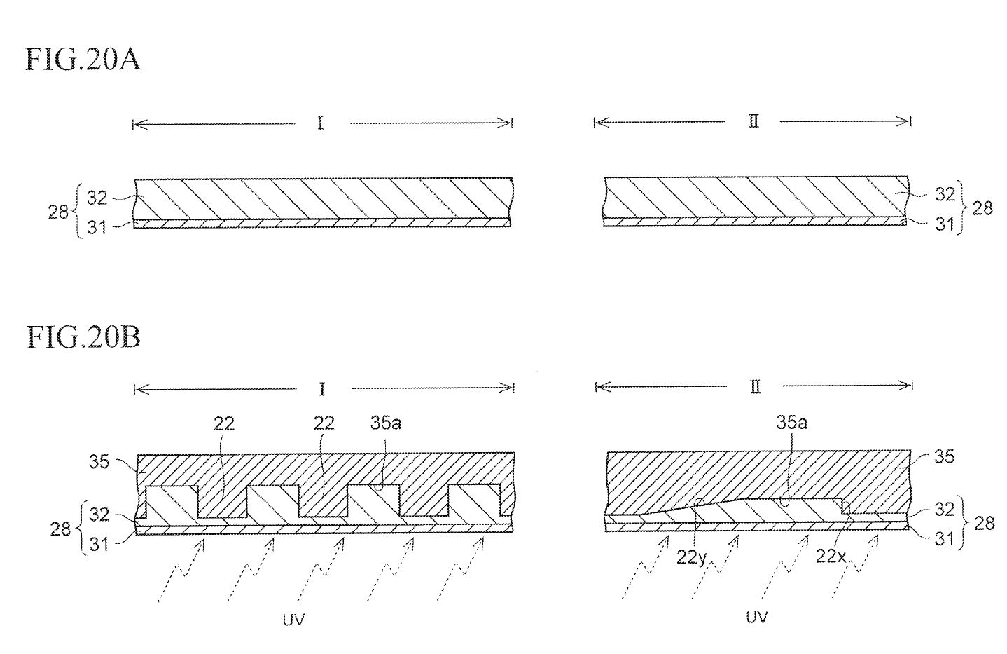

FIGS. 20A to 20D are cross-sectional views of the heat transfer device according to the present embodiment, which are in the course of the manufacturing process.

Note in FIGS. 20A to 20D that a first cross-section I and a second cross-section II are illustrated. The cross sectional plane of the first cross-section I is the plane that is perpendicular to the extending direction of the flow channel 22. The cross sectional plane of the second cross-section II is the plane that is parallel to the extending direction of the flow channel 22.

First, as illustrated in FIG. 20A, a coating 32 of an ultraviolet curable resin is formed on a base film 31, thus the base film 31 and the coating 32 are made into the first sheet 28. Although the material of the base film 31 is not particularly limited, a transparent resin film made of PET (polyethylene terephthalate) and the like can be used as the base film 31.

Subsequently, as illustrated in FIG. 20B, a die 35 whose surface is provided with a convex and concave pattern corresponding to the flow channel 22 on is prepared, and the die 35 is buried into the coating 32. Then, in this situation, the coating 32 is cured by irradiating the coating 32 with ultraviolet rays UV through the base film 31.

Thus, a portion of the flow channel 22 corresponding to a patterned surface 35a of the die 35 is formed in the first cross-section I.

Meanwhile, the step 22x and the inclined portion 22y of the flow channel 22 are formed in the second cross-section II, corresponding to the step and the inclination provided on the patterned surface 35a of the die 35.

Thereafter, as illustrated in FIG. 20C, the die 35 is detached from the coating 32.

Then, as illustrated in FIG. 20D, a PET sheet serving as the second sheet 29 is attached onto the first sheet 28 by using an unillustrated adhesive. Thus, the flow channel 22 is defined by the sheets 28 and 29.

Thereafter, while reducing the pressure in the flow channel 22, the working fluid C in an amount of about a half of the volume of the flow channel 22 is injected into the flow channel 22. Here, the injection of the working fluid C and the pressure reduction of the flow channel 22 are carried out through the first injection hole 22c (see FIG. 4) and the second injection hole 22d, and after the injection, the injection holes 22c and 22d are sealed off with an adhesive.

In this way, the basic structure of the heat transfer device 20 of the present embodiment is completed.

Note that although the flow channel 22 is formed by shaping the coating 32 of the ultraviolet curable resin in this example, the method of forming the flow channel 22 is not limited to this. For instance, the flow channel 22 may be formed by cutting surfaces of resin plates, glass plates, ceramic plates, and metal plates such as copper plates.

### Electronic Device

Next, examples of electronic devices including the heat transfer device 20 according to the present embodiment will be described.

### First Example

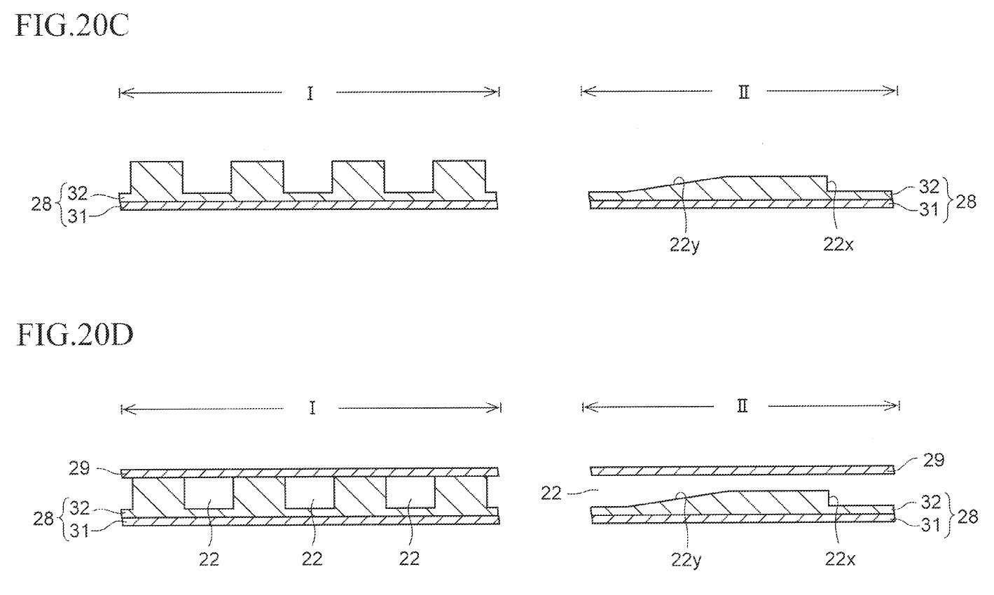

FIG. 21A is a front view of an electronic device 40 of the first example.

The electronic device 40 is a mobile device such as a smartphone, which includes a first housing 41 and a display unit 42. The display unit 42 is a liquid crystal display panel for example, which is exposed from the first housing 41.

Meanwhile, a speaker 43 for voice calls and a first camera 44 for video calls are provided at a rim of the first housing 41.

FIG. 21B is a rear view of the electronic device 40.

As illustrated in FIG. 21B, a second housing 45 including an opening 45a is provided on a back side of the electronic device 40. Moreover, a second camera 46 for taking still images and video images is exposed from the opening 45a.

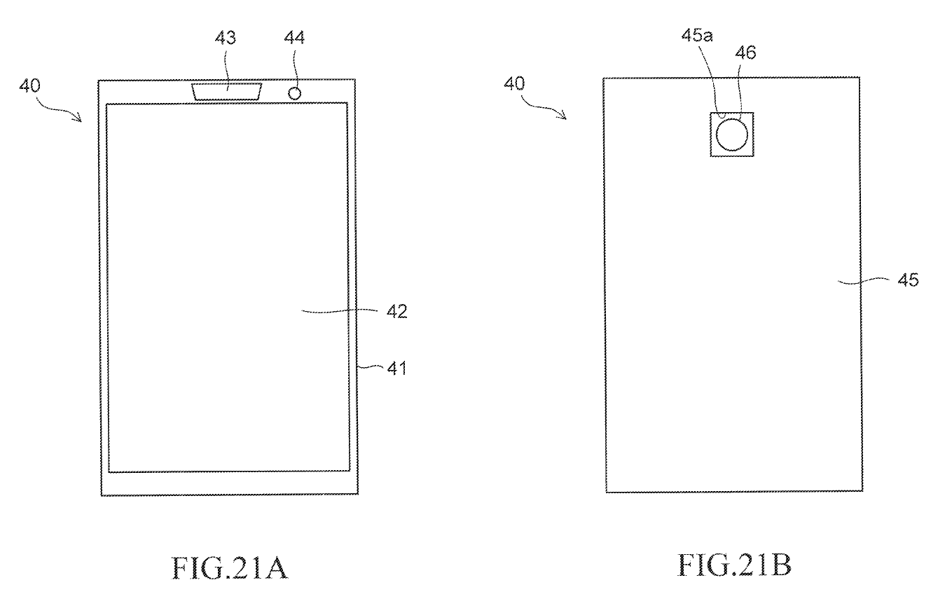

FIG. 22 is an exploded perspective view of the electronic device 40.

Note in FIG. 22 that the same elements as those explained in FIG. 4 are denoted by the same reference numerals as in FIG. 4, and description thereof will be omitted below.

As illustrated in FIG. 22, a battery 51, a circuit board 52, the electronic component 30, and the second camera 46 are housed in the above-mentioned first housing 41.

Among them, the electronic component 30 and the second camera 46 are driven by electric power supplied from the battery 51 through the circuit board 52.

Moreover, the above-described heat transfer device 20 is disposed between the first housing 41 and the second housing 45. In this example, the heated portion 23 of the heat transfer device 20 is opposed to the electronic component 30, and the cooled portion 24 of the heat transfer device 20 is brought into close contact with the second housing 45.

Here, in order to reduce thermal resistance between the cooled portion 24 and the second housing 45, a heat transfer sheet, a heat transfer grease, or the like may be interposed between the cooled portion 24 and the second housing 45.

According to the above-described electronic device 40, it is possible to cool the electronic component 30 with the heat transfer device 20, and to cool the cooled portion 24 of the heat transfer device 20 through the second housing 45.

In addition, since it is easy to thin the heat transfer device 20 as described previously, it is possible to appropriately cool the electronic component 30 without inhibiting the thinning of the electronic device 40.

### Second Example

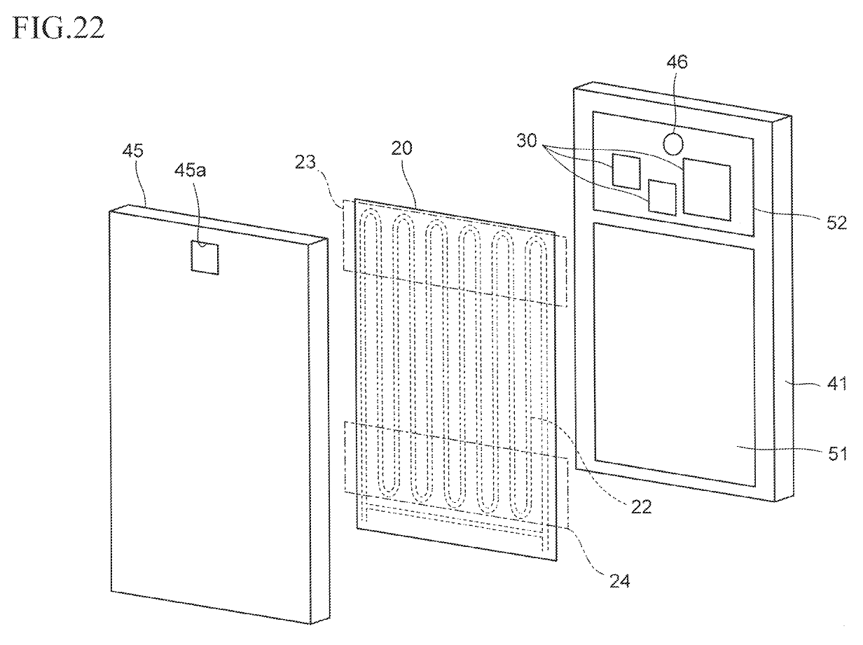

FIG. 23 is an exploded perspective view of an electronic device 60 of this example.

Note in FIG. 23 that the same elements as those explained in FIG. 22 are denoted by the same reference numerals as in FIG. 22, and description thereof will be omitted below.

As illustrated in FIG. 23, in the electronic device 60 of this example, the heat transfer device 20 also serves as a housing to house the electronic component 30, so that the flow channel 22 is formed in the housing.

According to this structure, the heat transfer device 20 is directly exposed to the outside air, so that the cooled portion 24 of the heat transfer device 20 can be promptly cooled with the outside air.

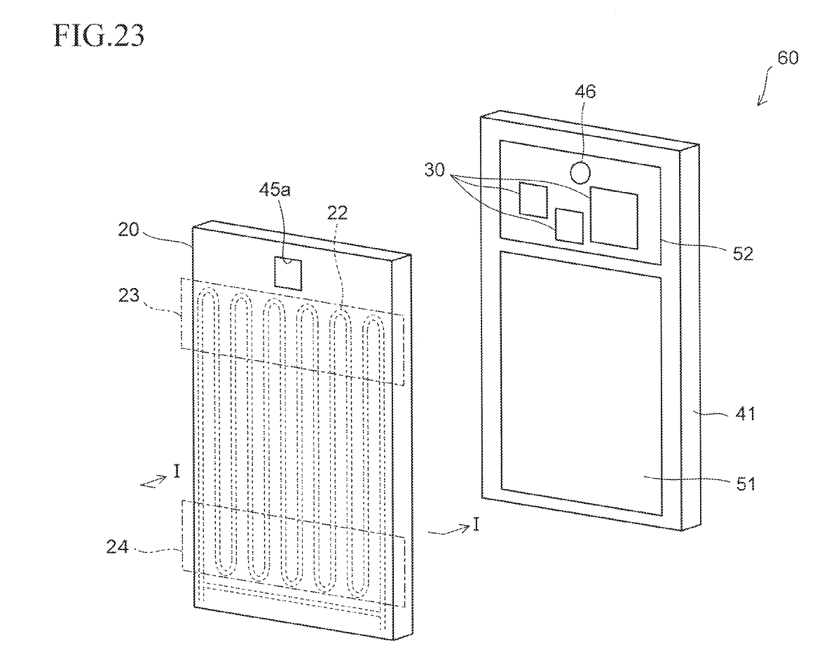

FIG. 24 is a cross-sectional view taken along the I-I line in FIG. 23.

As illustrated in FIG. 24, in this example, rims of the heat transfer device 20 are bent in conformity with an outer shape of the first housing 41 (see FIG. 23). Thus, the heat transfer device 20 can be fitted into the first housing 41, and the heat transfer device 20 and the first housing 41 can be mechanically connected to each other.

Here, the heat transfer device 20 of this example can be produced by attaching the first sheet 28 to the second sheet 29 as described with reference to FIGS. 20A to 20D.

### Third Example

This example explains attitudes in use of the electronic devices 40 and 60 described in the first and second examples.

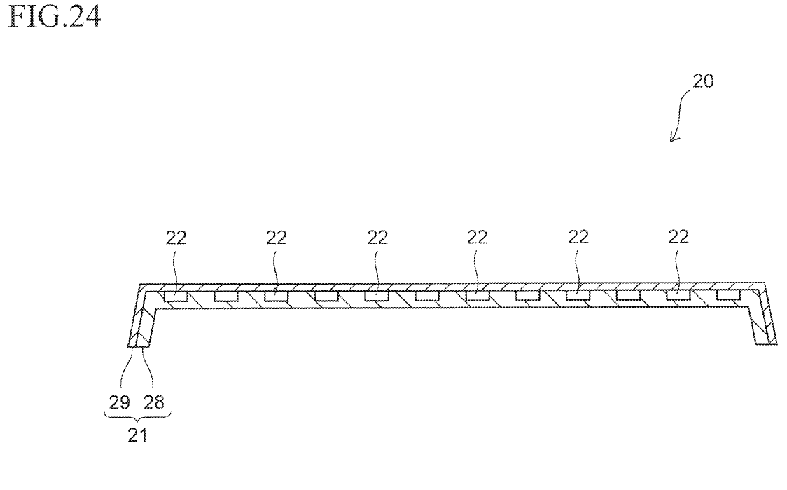

FIGS. 25 to 27 are perspective views illustrating the attitudes in use of the electronic devices 40 and 60. Note in FIGS. 25 to 27 that the same elements as those explained in FIGS. 21A, 21B, and 22 to 24 are denoted by the same reference numerals as in these figures, and description thereof will be omitted below.

Moreover, in FIGS. 25 to 27, a vertically downward direction is indicated with an arrow g.

In the example of FIG. 25, the electronic devices 40 and 60 are used in the vertically upright position.

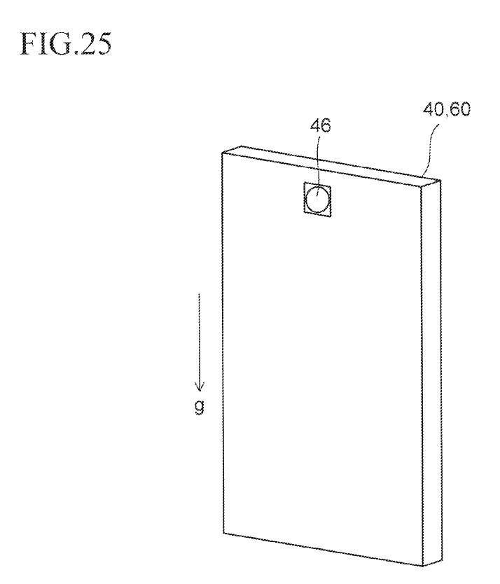

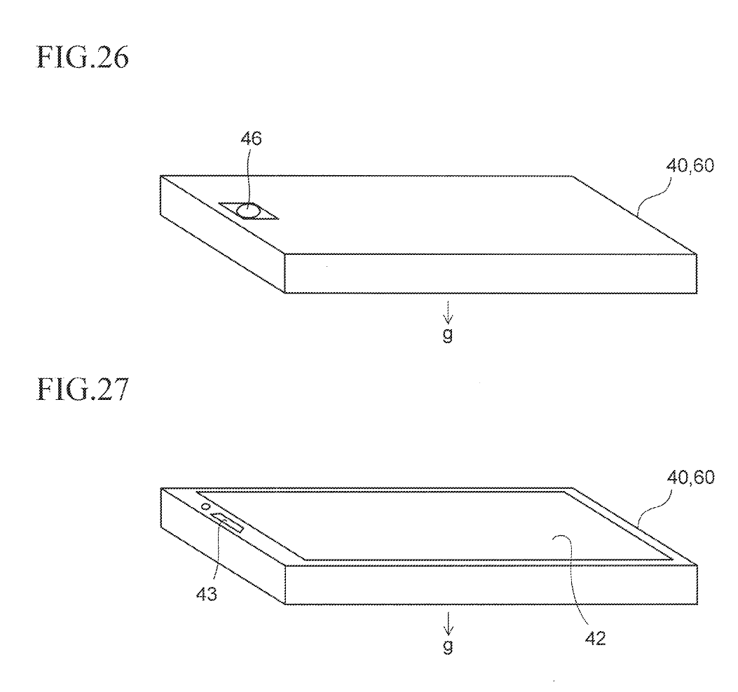

Meanwhile, in the examples of FIGS. 26 and 27, the electronic devices 40 and 60 are used while they are laid in the horizontal plane.

In any of the attitudes illustrated in FIGS. 25 to 27, the heat transfer device 20 can cool the electronic component 30 without causing an adverse effect on the performance of the heat transfer device 20.

All examples and conditional language recited herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A heat transfer device comprising:
a heated portion;
a cooled portion;
a closed loop-shaped flow channel meandering from the heated portion to the cooled portion;
a step that divides the flow channel at the heated portion into a first portion and a second portion, where the second portion has a smaller cross-sectional area than a cross-sectional area of the first portion; and
a working fluid enclosed in the flow channel.

2. The heat transfer device according to claim 1, wherein the first portion at the heated portion is longer than the second portion at the heated portion.

3. The heat transfer device according to claim 2, wherein
the flow channel at the heated portion includes a bent portion that is bent into a U-shape, and
the step is located at a position away from a peak of the bent portion.

4. The heat transfer device according to claim 1, wherein the cross-sectional area of the second portion is equal to or greater than 0.6 times but equal to or below 1.0 times as large as the cross-sectional area of the first portion.

5. The heat transfer device according to claim 1, wherein a height of the flow channel at the first portion is higher than a height of the flow channel at the second portion.

6. The heat transfer device according to claim 1, wherein the first portion occupies all of the flow channel at the cooled portion.

7. The heat transfer device according to claim 1, wherein an inclined portion inclined from the first portion toward the second portion is provided on an inner surface of the flow channel.

8. The heat transfer device according to claim 1, further comprising:
a sheet having a surface with which the flow channel is provided, wherein
the sheet below the flow channel includes a thin portion located on a lower side with respect to the step and having a first thickness, and
a thick portion located on an upper side with respect to the step and having a second thickness thicker than the first thickness.

9. An electronic device comprising:
a heat transfer device including a heated portion and a cooled portion; and
an electronic component thermally connected to the heated portion of the heat transfer device, wherein
the heat transfer device includes
a closed loop-shaped flow channel meandering from the heated portion to the cooled portion,
a step that divides the flow channel at the heated portion into a first portion and a second portion, where the second portion has a smaller cross-sectional area than a cross-sectional area of the first portion; and
a working fluid enclosed in the flow channel.

10. The electronic device according to claim 9, wherein the heat transfer device serves as a housing that houses the electronic component.
